(19) United States
(12) Patent Application Publication
(10) Pub. No.: US 2007/0285177 A1
(43) Pub. Date: Dec. 13, 2007

(54) SWITCHABLE PHASE LOCKED LOOP AND METHOD FOR THE OPERATION OF A SWITCHABLE PHASE LOCKED LOOP

(75) Inventor: Heinz Werker, Huglfing (DE)

Correspondence Address: PEARNE & GORDON LLP, 1801 EAST 9TH STREET, SUITE 1200, CLEVELAND, OH, 44114-3108, US

(73) Assignee: NATIONAL SEMICONDUCTOR GERMANY AG, Unterhaching (DE)

(21) Appl. No.: 11/751,178

(22) Filed: May 21, 2007

(30) Foreign Application Priority Data
May 24, 2006 (DE) 10 2006 024 471.0

(51) Int. Cl. H03L 7/00

(52) U.S. Cl. 331/16

(57) ABSTRACT

The invention relates to a phase locked loop or “PLL” (12) and a method of operating a PLL (12), wherein a controllable oscillator (DCO) generates an output signal (CKout) and it is possible to switch between a first clock (CKin1 or CKin2) and a second clock (CKin2 or CKin1) for use as a PLL (12) input clock. In accordance with the invention, for the clock (CKin1 or CKin2) currently being used to generate the output signal (CKout) a phase difference is determined between this clock and a preset phase-shifted version (CK<1:8>) of the output signal (CKout) and is used to control the oscillator (DCO), whereas for the clock (CKin2 or CKin1) not currently being used to generate the output signal (CKout), the phase shift is adjusted. In this way, a phase difference between several clocks (CKin1, CKin2, CKin3) used as the input clock is effectively adjusted or else compensated before the switchover, so that any unwanted phase change in the PLL output signal resulting from the switchover can be avoided with a high degree of accuracy and hitless switching achieved.

### BACKGROUND OF THE INVENTION

1. Field of the Invention

The present invention relates to a phase locked loop with a controllable oscillator for generating an output signal of the phase locked loop and with a switchover means for switching between a first clock and a second clock for use as the input clock of the phase locked loop.

Further, the invention relates to a method of operating a phase locked loop, wherein a controllable oscillator generates an output signal of the phase locked loop and it is possible to switch between a first clock and a second clock for use as a phase locked loop input clock.

2. Description of the Prior Art

A phase locked loop of this type, hereinafter also referred to in brief as “PLL”, and an operating method of this type for a PLL are known from U.S. Pat. No. 6,741,109, for example.

In general terms, a PLL is used to synchronise a controlled oscillator, which generates an output signal with an output frequency, by means of feedback with an input clock with an input frequency. For this purpose, the PLL comprises a phase detector or phase comparator to whose input the input clock and the PLL output signal are applied. A signal representing the phase difference between these two signals is mainly used via an active or passive, digital or analog filter (loop filter) to control the oscillator.

PLL circuits have various fields of application. For example, PLLs may be used for clock recovery from digital signal sequences or FM demodulation. In communications standards such as “SONET” or “SDH”, clock generation circuits are needed to generate clocks for data transmission and reception. In this sort of circuit, a PLL circuit may generate one or more output clocks, e.g. from an input clock provided as a reference, for use in a communications system. In this case, the synchronisation of the PLL output signal with an input clock does not necessarily mean that the frequencies of these two signals are identical. Rather, a more or less arbitrary frequency ratio may be achieved in a manner known per se by disposing frequency dividers at the input and/or output and/or in the feedback path of the PLL circuit.

The present invention assumes, as does the aforementioned U.S. Pat. No. 6,741,109, that with this sort of PLL it is possible to switch between a first clock and a second clock for use as a PLL input clock. In this case it is also possible that more than two clocks are used as PLL input clock. In fact, it is essential that only one clock is ever chosen out of several clocks and actually used to generate the PLL output signal. The provision of several clocks may be advantageous, particularly when it comes to creating redundancy in a communications system. If, for instance, one of the clocks being used as a reference is “lost”, a switch can be made to another clock for use as the PLL input clock in the clock generation PLL circuit. In this case it is desirable, particular for using the PLL in communications systems for clock production or clock recovery, for there to be no significant phase change (“phase hit”) in the PLL output signal due to such a switchover. However, this sort of phase change may occur if the first and second clocks are at different phases immediately before the switch.

A known possibility for avoiding erratic phase changes as a consequence of a switchover involves choosing a very low PLL bandwidth (“loop gain”) (in the order of a few Hz, for example, in the aforementioned communications systems). In this case, the phase of the PLL output signal only changes very slowly even if the clocks being switched between have a comparatively large phase difference immediately before switching. In the aforementioned communications systems, no data transmission errors occur in this case. However, this solution includes for example the following two disadvantages: Firstly, a particularly low PLL bandwidth is hard to achieve in an integrated circuit arrangement. Secondly, a low PLL bandwidth also results in a disadvantageously smaller capture range for the PLL. For a PLL bandwidth of a few Hz, the PLL capture range may be smaller than 1 ppm, for instance.

The aforementioned U.S. Pat. No. 6,741,109 suggests that in order to avoid phase changes in the PLL output signal resulting from a switchover or to guarantee “hitless switching”, the phase difference for the clock not currently being used to generate the output signal should be determined in relation to a feedback signal derived from the PLL output signal and stored. If a switch occurs to this clock, the stored phase difference is injected into the PLL at a suitable point, in order to compensate for the phase difference. A problem with this solution is the compensation accuracy that can be achieved in practice and the switching expenditure required for the compensation.

### SUMMARY OF THE INVENTION

An object of the present invention is to improve a phase locked loop or else a method of the type mentioned above, such that unwanted phase changes in the output signal resulting from a switchover can be reliably avoided.

The phase locked loop according to the invention is characterised in that a phase detector that can be switched between different operating modes is provided for the two clocks, wherein the phase detector for the clock currently being used is put into a first operating mode and the phase detector for the clock not currently being used is put into a second operating mode, and wherein each phase detector in the first operating mode determines a phase difference between the clock used and a preset phase-shifted version of the output signal and supplies it to control the oscillator and sets the phase shift in the second operating mode.

The operating method according to the invention is characterised in that for the clock currently being used to generate the output signal a phase difference is determined between this clock and a preset phase-shifted version of the output signal and is used to control the oscillator, whereas for the clock not currently being used to generate the output signal, the phase shift is adjusted.

The compensation accuracy or quality of hitless switching can be improved significantly by the invention. This is achieved advantageously with comparatively low circuit-technical expenditure. In the invention, any phase difference existing between several clocks used as an input clock is effectively adjusted or else compensated before the switchover, so that particularly any unwanted phase change in the PLL output signal resulting from the switchover, can be avoided with a high degree of accuracy. This does not require a very low PLL bandwidth. On the contrary, the solution according to the invention is compatible with a high PLL bandwidth.

In a preferred embodiment of the method, it is envisaged that the output signal is supplied with several phases and the phase-shifted version of the output signal is generated by an adjustable interpolation between these phases. In the PLL according to the invention, for instance, this can be achieved by the oscillator being of such a design that the output signal is supplied to the phase detector with several phases, wherein the phase detector comprises:
an adjustable phase interpolator for interpolation between these phases and provision of a preset interpolated signal, and
a phase comparator means for comparing the clock phase with the interpolated signal phase and for supplying a phase detector output signal representing the phase difference.

In another preferred embodiment of the method it is envisaged that for the clock not currently being used to generate the output signal, the phase shift setting should be accomplished by a phase control, in which a signal representing the phase difference is controlled by using this signal to adjust the output signal phase shift. In the PLL according to the invention, this may be achieved, for instance, by the phase detector comprising a phase locked loop activated in the second operating mode, which controls a phase detector output signal representing the phase difference by this phase detector output signal being used to adjust a phase shifting means, which generates the phase-shifted version of the output signal. The phase shifting means may be, for example, the phase interpolator mentioned above.

It is envisaged in an embodiment that the phase detector generates a phase detector output signal digitally representing the phase difference. In this case, the phase detector output signal may pass through a digital filter, which supplies a control signal for a digitally controlled oscillator (DCO). It goes without saying that an analog voltage-controlled oscillator (VCO) could also be used by making a corresponding modification to the PLL filter.

### BRIEF DESCRIPTION OF THE DRAWINGS

The invention is further described below on the basis of an exemplary embodiment with reference to the attached drawings. In the figures:

FIG. 1 shows a PLL circuit,

FIG. 2 shows the design of the phase detectors used in the PLL circuit in FIG. 1,

FIG. 3 shows the design of a sampler means used in the phase detector in FIG. 2,

FIG. 4 shows the design of a multi-phase sampler used in the sampler means in FIG. 3,

FIG. 5 shows an exemplary diagram showing the variation in time of signals occurring at the multi-phase sampler in FIG. 4,

FIG. 6 shows the design of a phase interpolator used in the phase detector in FIG. 2, and

FIG. 7 shows the design of two interpolator halves used in the phase interpolator in FIG. 6.

### DESCRIPTION OF THE PREFERRED EMBODIMENT(S)

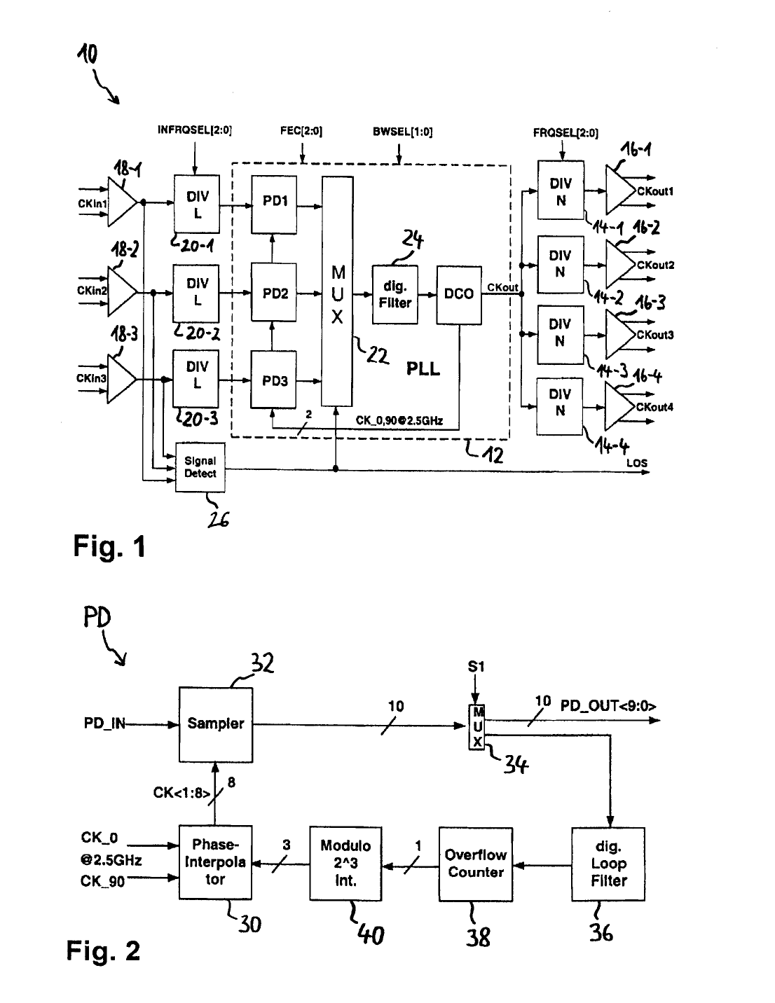

FIG. 1 shows a PLL circuit 10 with a PLL (phase locked loop) 12.

The PLL 12 has a digitally controlled oscillator (DCO) for generating an output signal CKout or else a two-phase version of this output signal with two phases CK_0 and CK_90. The two signals CK_0, CK_90 have a fixed phase difference relative to one another of 90° and fixed phase differences relative to the output signal CKout. In the simplest case, the signal CKout is identical to one of the signals CK_0 and CK_90.

In the exemplary embodiment shown, the PLL output signal CKout is fed to several output dividers 14-1 to 14-4, which divide the PLL output signal frequency in each case based on a predetermined division ratio and emit it to output stages 16-1 to 16-4, which convert the signal into a differential output clock CKout1 to CKout4 in each case.

At the input end, several differential clocks CKin1 to CKin3 are supplied to the circuit 10, which are initially converted into a non-differential representation by three input stages 18-1 to 18-3 and are inputted into the PLL 12 via three input dividers 20-1 to 20-3.

For each of the clocks CKin1 to CKin3, hereinafter also referred to as “input signal CKin”, a phase detector PD1, PD2 or PD3 is provided as illustrated.

Each of these phase detectors PD1 to PD3, hereinafter also referred to as “phase detector PD”, is capable in a given operating mode (“first operating mode”) of determining a phase difference between the clock CKin concerned (or else the frequency-divided version thereof generated by the divider 20-1, 20-2 or 20-3) and a preset phase-shifted version of the output signal CKout and supplying it to control the digitally controlled oscillator (DCO). To this end, the outputs of the phase detectors PD are connected to a multiplex or switchover means 22, which is designed to select one of the three signals emitted by the phase detectors PD1 to PD3 and emit it to a PLL filter 24. In the exemplary embodiment shown, each phase detector PD produces in its first operating mode a phase detector output signal digitally representing this phase difference, which is filtered by the PLL filter 24 digitally designed in this exemplary embodiment and emitted to a control input of the oscillator DCO. The frequency of the PLL output signal CKout emitted by the DCO is controlled by the signal emitted by the PLL filter 24.

It is therefore possible to switch between the three clocks CKin1 to CKin3 used as the PLL input clock by means of the switchover device 22. Each switchover of this type is initiated by a signal detection means 26, which is acted upon by the clocks CKin1 to CKin3 at the input end, as illustrated, and is connected to the switchover means 22 at the output end. The means 26 detects the quality of the clocks CKin and makes a decision on the basis of this detection as to which of the clocks is to be used as the PLL input clock or else which other input clock is to be switched to, if the clock currently being used becomes unusable. The latter situation is also communicated to other parts of an integrated circuit arrangement (not shown), which also includes the illustrated PLL circuit 10, by means of a LOS signal.

FIG. 2 illustrates the (identical) design of the three phase detectors PD1, PD2 and PD3. Due to the identical design of the three phase detectors, this design is only described for one phase detector PD in relation to FIG. 2. All components and signals described below for the phase detector PD exist separately for each of the phase detectors PD1 to PD3 in the circuit 10 illustrated in FIG. 1.

The essential components for the first operating mode of the phase detector PD, as already mentioned above, are an adjustable phase interpolator 30 and a sampler means 32. The two “quadrature signals” CK_0 and CK_90 of the PLL output signal CKout are inputted to the phase interpolator 30. In accordance with an interpolation setting described later, the interpolator 30 generates a preset interpolated signal CK<1:8>, which is fed to the sampler means 32 as an input signal. In the exemplary embodiment shown, the phase interpolator 30 interpolates between the two sinusoidal quadrature clocks CK_0, CK_90 of the DCO, which oscillates at a frequency of around 2.5 GHz. The signal representation CK<1:8> consists of eight signal portions and represents a “phase-shifted version of the PLL output signal” CKout (according to the interpolation setting). The sampler means 32 functions as a phase comparator and compares the phase-shifted version CK<1:8> of the output signal CKout (fed to the phase detector PD as quadrature signal parts CK_0 and CK_90) with the phase of a phase detector input signal PD_IN. As a result of this comparison, the sampler means 32 generates a digital signal representation PD_OUT<9:0>, which is fed to the phase detector output connected to the PLL switchover means 22 (FIG. 1) via a phase detector switchover means 34 in the phase detector PD's first operating mode. The phase detector input signal PD_IN illustrated in FIG. 2 is one of the signals emitted by the input dividers 20-1 to 20-3 illustrated in FIG. 1.

Returning once again to FIG. 1, it is assumed below, for instance, that having been initiated by the signal detection means 26 and implemented by the PLL switchover means 22, the clock CKin1 is currently being used as the input clock of PLL 12 and a switchover to clock CKin2 will take place at a later time. In this situation, the phase detector PD1 is in its first operating mode, which was explained earlier in relation to FIG. 2. The other two phase detectors PD2 and PD3 are, however, in a second operating mode, which is once again described below with reference to FIG. 2, in which these supply no input clock for the PLL.

The switchover of the phase detector PD illustrated in FIG. 2 from its first operating mode to its second operating mode is effected by a signal S1 emitted by the signal detection means 26 or the PLL switchover means 22, which controls or triggers the phase detector switchover means 34 in such a way that the phase detector output signal PD_OUT<9:0> emitted by the sampler means 32 is no longer emitted as the reference clock signal to the PLL, but acts back on the phase interpolator 30 via a feedback path provided in the phase detector PD. In the exemplary embodiment depicted, this feedback path is created by a digital filter 36, an overflow counter 38 and a modulo-8 integrator 40.

In the second operating mode, the phase detector output signal PD_OUT<9:0> is fed via the digital filter 36 to an input of the overflow counter 38, which emits an output pulse to the Modulo-8 integrator 40 for each counter overflow. The integrator 40 emits a setting signal for the adjustable phase interpolator 30 at the output end, for which eight different signal states are provided corresponding to eight different interpolation stages.

Due to the fact that in the second operating mode of the phase detector PD the setting of the phase interpolator 30 influences the phase of the signal CK<1:8> and therefore directly influences the phase detector output signal PD_OUT<9:0> used for the interpolation setting, a phase control is carried out in the phase detector PD, whereby the setting emitted by the integrator 40 is varied until a situation is reached in which the phase detector output signal is controlled to a value corresponding to a phase difference of zero. If the phase detector PD is active and included in the PLL, the entire feedback path 36, 38, 40 is inactive.

This phase control is carried out in all phase detectors PD not currently used to generate the PLL output signal. This effectively creates an “internal phase setting” in relation to the PLL output signal for all the different clocks CKin, even before there is a switchover between the clocks CKin for use as the PLL input clock. The function of this internal phase control, which takes place in the second operating mode of each phase detector PD, can to some extent be seen as a “PLL within the phase detector”. With the components 38, 40, 30, the function of a digitally controllable oscillator for this “internal PLL” is provided.

If there is now a switchover in the PLL circuit 10 (FIG. 1) to a clock not previously used for PLL output signal generation, the internal switchover means 34 in the phase detector PD concerned is changed by the signal S1 in such a way that the phase detector output signal PD_OUT<9:0> is supplied to the PLL filter 24 via the likewise correspondingly switched PLL switchover means 22. On account of the previous controlled setting of the phase interpolator 30 by means of the “internal PLL”, this switchover does not lead to a detrimental phase change in the PLL output signal (as could be expected if the phase interpolator 30 had not be correspondingly set beforehand).

Something crucial to the operation of the PLL circuit 10 described is the use of a PLL 12, whereby it is possible to switch between several clocks for use as the PLL input clock, wherein the PLL phase detector currently being used in each case compares the phase of a preset phase-shifted feedback signal with the phase of the currently used input signal and currently unused phase detectors undertake a setting of the phase shift in this period, which is used as the “initial setting” if it is used as the PLL phase detector. It goes without saying that a different number of clocks can also be provided at the input and/or a different number of output clocks from that in the exemplary embodiment described. Furthermore, the number and arrangement of the frequency dividers 14, 16 can be adapted to the respective use. The phase detector PD design illustrated in FIG. 2 represents a preferred exemplary embodiment, but it could of course also be realised in a different way. However, a preferred design is one in which (as with the described design), an internal phase locked loop is realised within the phase detector to set the phase shift in the second operating mode. With regard to the phase shift itself, the described realisation by means of a phase interpolator should also only be regarded as a preferred embodiment, which could also be designed differently. The same applies to the detail configuration described below of the sampler means 32, on the one hand, and the phase interpolator 30, on the other, which could also be designed differently to the way described below.

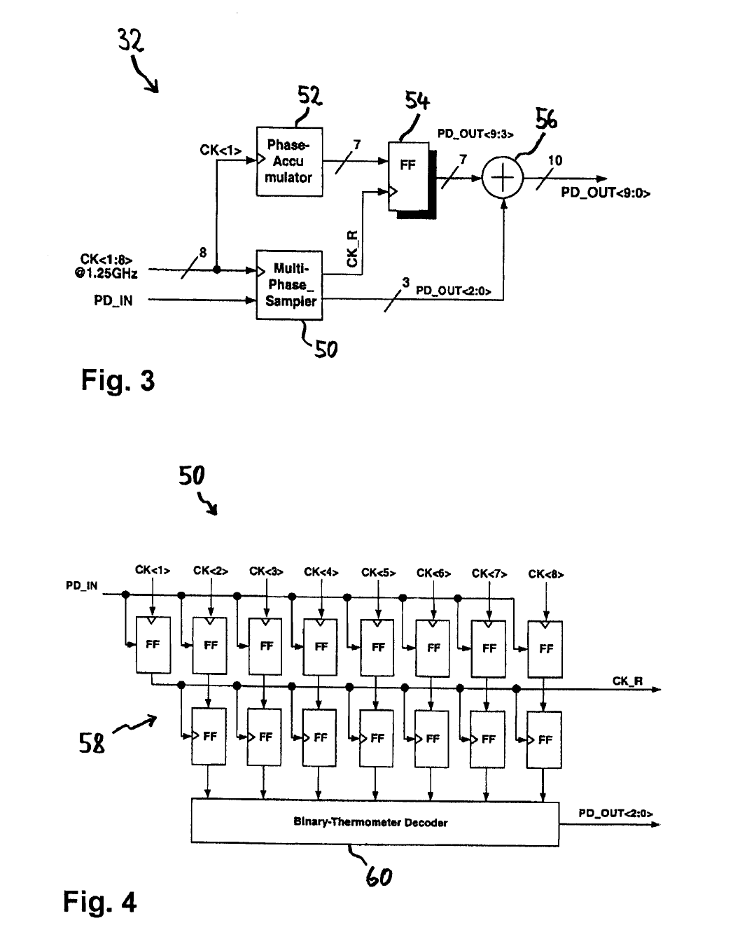

FIG. 3 shows the design of the sampler means 32 used in the phase detector PD from FIG. 2.

The phase-shifted version CK<1:8> of the PLL output signal CKout and the phase detector input signal PD_IN is fed into a multi-phase sampler 50, which produces signals CK_R and PD_OUT<2:0> from it. A signal portion CK<1> of the signal CK<1:8>, which is made up of a total of eight signal portions CK<1> to CK<8>, is furthermore fed into a phase accumulator 52 (counter). A flip-flop arrangement 54 consisting of seven flip-flops is acted upon, as illustrated, by a signal emitted by the phase accumulator 52 and also signal CK_R and forms a signal portion PD_OUT<9:3>, which creates the phase detector output signal PD_OUT<9:0> via a summation block 56 further acted upon by the signal PD_OUT<2:0>. In the exemplary embodiment shown, the sampler means 32 produces a 10-bit word at its output, which digitally represents the phase difference of the signals supplied to the phase detector PD. The sampler means 32 comprises the high-speed multi-phase sampler used to supply the signal PD_OUT<2:0>, which represents the three lowest value bits of the phase detector output signal. The flip-flop arrangement 54 produces the 7 highest value bits. The multi-phase sampler samples the phase detector signal PD_IN supplied, which has a frequency of 19.44 MHz in the example illustrated, with the 8 evenly spaced clocks CK<1> to CK<8>, which have a frequency of 1.25 GHZ in the exemplary embodiment shown and supply a phase resolution of 100 ps.

FIG. 4 shows the design of the multi-phase sampler 50 illustrated in FIG. 3. The multi-phase sampler 50 comprises, as illustrated, a flip-flop arrangement 58 and a decoder 60, which are acted upon in the manner illustrated by the signals PD_IN and CK<1> to CK<8> and emit signals CK_R and PD_OUT<2:0> at the output end.

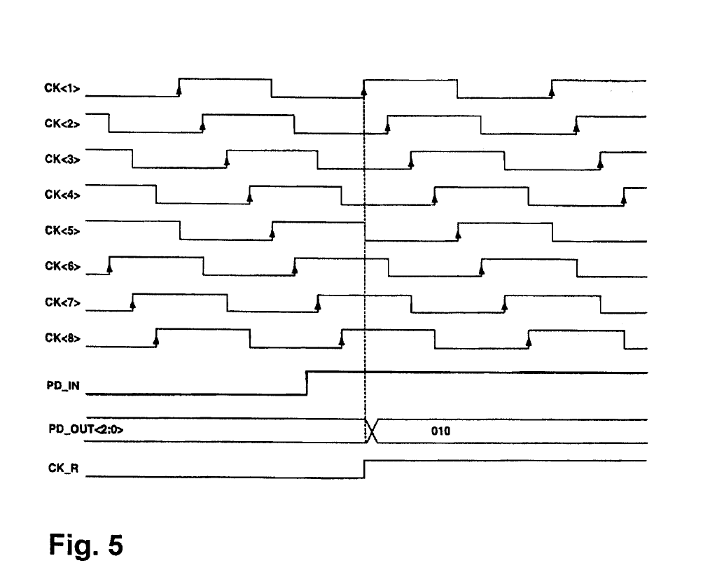

FIG. 5 shows an exemplary time response of the signal portions CK<1> to CK<8>, signal PD_IN, signal PD_OUT<2:0>, and signal CK_R. FIG. 5 shows, in particular, the phase relationship between the 8 sampler clocks CK<1:8> and the phase detector input signal PD_IN and the phase detector output signal PD_OUT.

It is evident from this that the signal portions CK<1> to CK<8> produced by the phase interpolator 30 are signals that are identical to one another, but phase-shifted at an equal distance to one another. In the exemplary embodiment illustrated, the staggering in time between two adjacent signal portions (e.g. between CK<1> and CK<2>) is 100 ps.

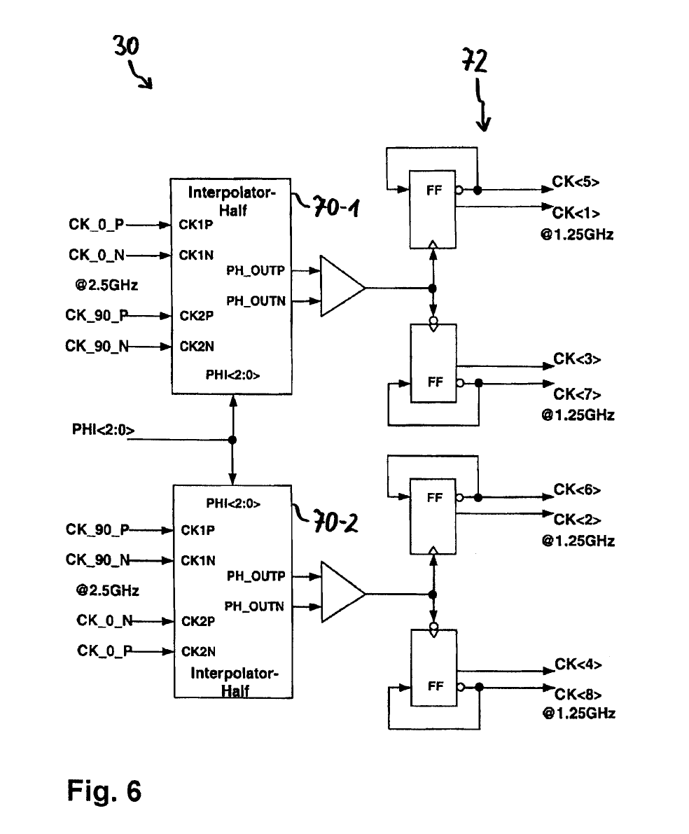

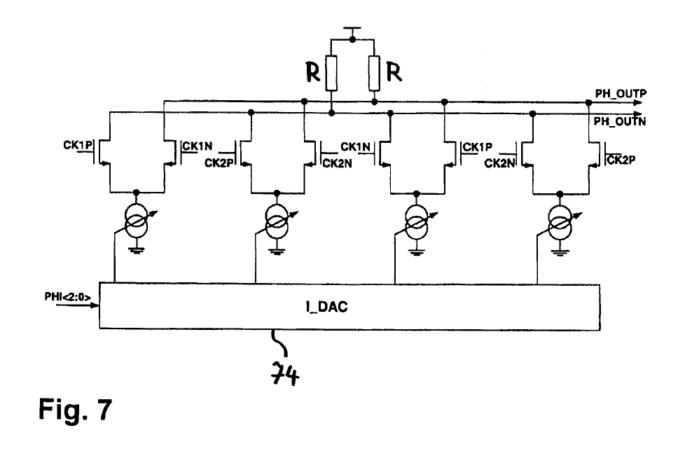

FIGS. 6 and 7 illustrate the design of phase interpolator 30.

The overall design of the interpolator 30 is shown in FIG. 6. In order to supply the eight evenly spaced (at 100 ps intervals) clocks CK<1> to CK<8> at a frequency of 1.25 GHz, the interpolator 30 comprises the two illustrated halves 70-1 and 70-2 and an output circuit part 72 with additional divider circuits. The interpolator halves 70-1, 70-2 and the interpolator output circuit part 72 interact in the manner shown to create the phase-shifted version of the PLL output signal from the quadrature signals CK_0 and CK_90 (cf. FIG. 1), represented by the signal components CK<1> to CK<8>.

The quadrature signals CK_0 and CK_90 are fed to the interpolator 30 in differential form: The signal CK_0 consists of differential signal portions CK_0_P and CK_0_N. The signal CK_90 consists of differential signal portions CK_90_P and CK_90_N. The desired phase shift is set by the signal PHI<2:0>. This is the signal transmitted in FIG. 2 from the Modulo-8 integrator 40 to the control input of the phase interpolator 30.

Finally, FIG. 7 shows the (identical) design for the two interpolator halves 70-1 and 70-2 shown in FIG. 6. The design of each interpolator half follows a concept known per se and comprises a digital-analog converter 74 that converts the supplied signal PHI<2:0> into a current representation (symbolised by the current sources illustrated). The currents supplied by the current sources serve as setting currents for respective transconductance stages, which, as illustrated, are each formed by transistor pairs and bring about a weighted superposition of the individual currents. These currents are fed across a joint resistance load R, so that the potentials PH_OUTP and PH_OUTN shown in FIG. 6 are supplied as a voltage drop at the resistor load R. The phase interpolator output signal corresponds to the weighted sum of the CK1 and CK2 input signals obtained (by current superposition), which have a constant phase difference of 90°. The resolution of the phase interpolator output signal is specified as 50 ps.

The frequency and time values given for the aforementioned exemplary embodiment should of course only be regarded by way of example and can be modified in practice and adapted to the particular application concerned.

1. A phase locked loop (12) with a controllable oscillator (DCO) for generating an output signal (CKout) of the phase locked loop and with a switchover means (22) for switching between a first clock (CKin1) and a second clock (CKin2) for use as the input clock of the phase locked loop,
characterised in that a phase detector (PD1, PD2) that can be switched between different operating modes is provided for each of the two clocks (CKin1, CKin2), wherein the phase detector (PD1 or PD2) for the clock currently being used (CKin1 or CKin2) is put into a first operating mode and the phase detector (PD2 or PD1) for the clock not currently being used (CKin2 or CKin1) is put into a second operating mode, and wherein each phase detector (PD1, PD2) in the first operating mode determines a phase difference between the clock used (CKin1 or CKin2) and a preset phase-shifted version (CK<1:8>) of the output signal (CKout) and supplies it to control the oscillator (DCO) and sets the phase shift in the second operating mode.

2. The phase locked loop according to claim 1, wherein the oscillator (DCO) is designed to supply the output signal (CKout) with several phases (CK_0, CK_90) for the phase detector (PD1, PD2, PD3), and wherein the phase detector (PD1, PD2, PD3) comprises:
an adjustable phase interpolator (30) for interpolation between these phases (CK_0, CK_90) and provision of a preset interpolated signal (CK<1:8>), and
a phase comparator means (32) for comparing the clock (CKin1, CKin2, CKin3) phase with the interpolated signal (CK<1:8>) phase and for provision of a phase detector output signal (PD_OUT<9:0>) representing the phase difference.

3. The phase locked loop according to claim 1, wherein the phase detector (PD1, PD2, PD3) comprises a phase locked loop (36, 38, 40, 30) activated in the second operating mode, which controls a phase detector output signal (PD_OUT<9:0>) representing the phase difference by this phase detector output signal being used to adjust a phase shifting means (30), which generates the phase-shifted version (CK<1:8>) of the output signal (CKout).

4. The phase locked loop according to claim 1, wherein the phase detector (PD1, PD2, PD3) generates a phase detector output signal (PD_OUT<9:0>) digitally representing the phase difference.

5. A method of operating a phase locked loop (12), wherein a controllable oscillator (DCO) generates an output signal (CKout) of the phase locked loop and it is possible to switch between a first clock (CKin1) and a second clock (CKin2) for use as a phase locked loop input clock,
characterised in that for the clock (CKin1 or CKin2) currently being used to generate the output signal (CKout) a phase difference is determined between this clock and a preset phase-shifted version (CK<1:8>) of the output signal (CKout) and is used to control the oscillator (DCO), whereas for the clock (CKin2 or CKin1) not currently being used to generate the output signal (CKout), the phase shift is adjusted.

6. The method according to claim 5, wherein the output signal (CKout) is supplied with several phases (CK_0, CK_90) and the phase-shifted version (CK<1:8>) of the output signal (CKout) is generated by an adjustable interpolation between these phases (CK_0, CK_90).

7. The method according to claim 5, wherein for the clock (CKin2 or CKin1) not currently being used to generate the output signal (CKout), the phase shift setting is accomplished by a phase control, in which a signal representing the phase difference (PD_OUT<9:0>) is controlled by using this signal to adjust the output signal (CKout) phase shift.
